(19) United States
(12) Patent Application Publication
(10) Pub. No.: US 2008/0038480 A1
(43) Pub. Date: Feb. 14, 2008

(54) Plasma method for biomedical material onto hydrophilic polymer sheet

(75) Inventors: Te-Hsing Wu, Taoyuan City (TW); Ko-Shao Chen, Taipei City (TW); Lie-Hang Shen, Jhongli City (TW); Bin Lin, Hualien City (TW)

Correspondence Address: TROXELL LAW OFFICE PLLC, 5205 LEESBURG PIKE, SUITE 1404, FALLS CHURCH, VA, 22041, US

(73) Assignee: ATOMIC ENERGY COUNCIL-INSTITUTE OF NUCLEAR ENERGY RESEARCH, Taoyuan (TW)

(21) Appl. No.: 11/503,267

(22) Filed: Aug. 14, 2006

(51) Int. Cl. C23C 16/00; H05H 1/24

(52) U.S. Cl. 427/569; 427/255.6

(57) ABSTRACT

A plasma method is invented to prepare a biomedical material onto hydrophilic polymer sheet. A hydrophilic polymer film is formed with a good water contact angle. The present invention can be applied to artificial catheter, wound dressings and other dressings.

### FIELD OF THE INVENTION

The present invention relates to a plasma method; more particularly, relates to preparing a biomedical material having hydrophile and bio-compatibility.

### DESCRIPTION OF THE RELATED ARTS

Environment protection and health caring are two of the major concerns to human's life today. Green productions and health caring medicines therefore become more and more popular. Titanium dioxide is a diode having great abilities in oxidation and reduction and is made into a photo catalysis widely used for defogging, deodorizing and sterilizing. Regarding fabric base, porous polymer is used. For example, stretchable Teflon, like expanded PTFE (ePTFE), is porous, safe and biocompatible and is suitable to be applied in a nano-grade processed material. But, stretchable Teflon is a bioinert material and is a non-decomposable material having a water repellent surface. Thus, a surface modification is required to such a material to function well.

There are a few methods for the surface modification. Low-temperature plasma is one of them that does not destroy surface structure and can be operated under a normal environment with low pollution. A prior art of preparing a temporary wound dressing by surface grafting polymerization with gamma-ray irradiation is revealed. A plasma is used or a gamma-ray is irradiated on a material surface for grafting with a hydrophilic monomer, like acrylamide or itaconic acid, to improve hydrophile for hydrophilic decomposable polymer. Then a nonwoven wound dressing is made easy-stripped. Then a biodegradable material, like gelatin, chondroitin-6-sulfate or chitosan, is fixed on the surface of the dressing with special functional group, like —NH₂, polymerized on a grafting layer. By doing so, a bio-compatibility is gained to help histiocyte on regenerating and repairing. On considering that wound is apt to be infected by germs in the air, an anti-bacterial agent is further applied to prevent unwanted result to the wound owing to the infection. The dressing is irradiated by gamma-ray or is processed through a plasma activation treatment and is processed with a surface grating polymerization using a monomer, like NIPAAm, AAm or Itaconic acid. Or, the dressing is directly processed through a grating polymerization with gamma-ray for surface grating. Hence, an immobilization with chemical cross-linking is used to fix different biodegradable protein to obtain biodegradability and regeneration ability. In the other hand, different fixing methods are applied to different contact area of air coordinated with different chemical structures of anti-bacterial agents.

Although the above prior art prepares an anti-bacterial and hydrophilic biomedical material, the procedure is complex and a few agent are required. Hence, the prior art does not fulfill users' requests on actual use.

### SUMMARY OF THE INVENTION

The main purpose of the present invention is to process a polymer film through a plasma deposited treatment and a plasma activation treatment, where the processes are simple and no agent of initiator or catalyst is required.

To achieve the above purpose, the present invention is a plasma method for a biomedical material onto hydrophilic polymer sheet, comprising the following steps: (a) obtaining a polymer film to be cleaned with ultrasonic wave using an ethanol or a distilled water; and (b) processing the cleaned polymer film through a plasma deposited treatment under a vacuum pressure with hexamethyldisilazane having a pressure to form a hydrophilic polymer film, where, after step (b), the hydrophilic polymer film is further processed through a plasma activation treatment with oxygen to improve hydrophile. Accordingly, a novel plasma method for a biomedical material onto hydrophilic polymer sheet is obtained.

### BRIEF DESCRIPTIONS OF THE DRAWINGS

The present invention will be better understood from the following detailed descriptions of the preferred embodiments according to the present invention, taken in conjunction with the accompanying drawings, in which

FIG. 1 is the view showing the flow chart according to the present invention;

FIG. 2 is the view showing the flow chart of the first preferred embodiment;

FIG. 2A and FIG. 2B are the views showing the changes in hydrophile and the Fourier transform infrared spectrum of the first preferred embodiment;

FIG. 3 is the view showing the flow chart of the second preferred embodiment; and

FIG. 3A and FIG. 3B are the views showing the changes in hydrophile and the Fourier transform infrared spectrum of the second preferred embodiment.

### DESCRIPTIONS OF THE PREFERRED EMBODIMENTS

The following descriptions of the preferred embodiments are provided to understand the features and the structures of the present invention.

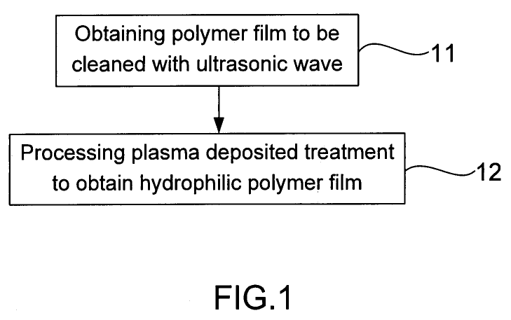

Please refer to FIG. 1 which is a view showing a flow chart according to the present invention. As shown in the figure, the present invention is a plasma method for a biomedical material onto hydrophilic polymer sheet, comprising the following steps:

(a) Obtaining a polymer film to be cleaned with ultrasonic wave [11]: A polymer film is obtained to be cleaned with ultrasonic wave using an ethanol or a distilled water, where the polymer film is made of a stretchable Teflon or a poly lactic-co-glycolic acid (PLGA).

(b) Processing a plasma deposited treatment to obtain a hydrophilic polymer film [12]: The cleaned polymer film is processed through a plasma deposited treatment under a vacuum pressure with hexamethyldisilazane (HMDSZ) having a pressure to form a hydrophilic polymer film, where the plasma deposited treatment is processed with a source of 13.56 MHZ RF; the vacuum pressure is below 20 mtorr; the plasma deposited treatment is processed for more than 5 minutes (min); the HMDSZ has a pressure between 40 mtorr to 60 mtorr; and the working power is between 5 watts (W) to 20 W. Thus, after the plasma deposited treatment, an organic silicon film is formed on the polymer film with improved hydrophile. Hence, a novel plasma method for a biomedical material onto hydrophilic polymer sheet is obtained.

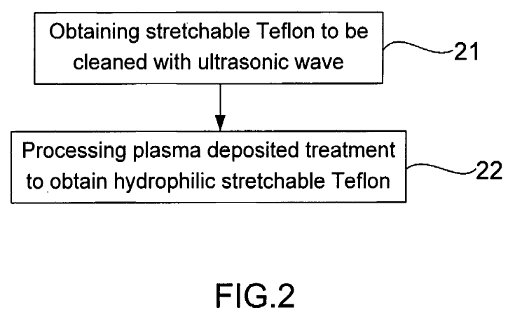

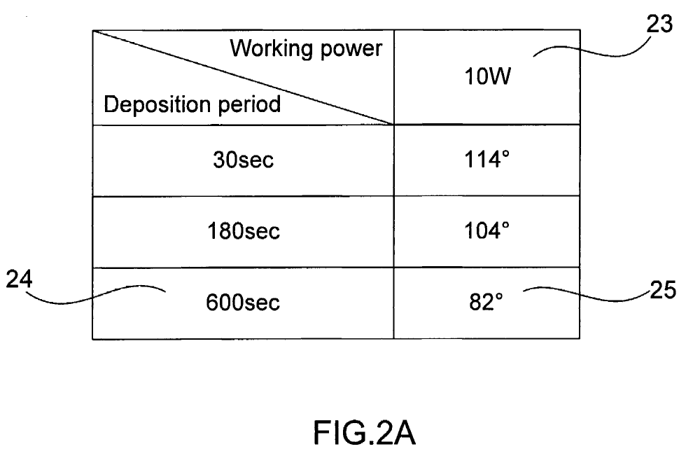

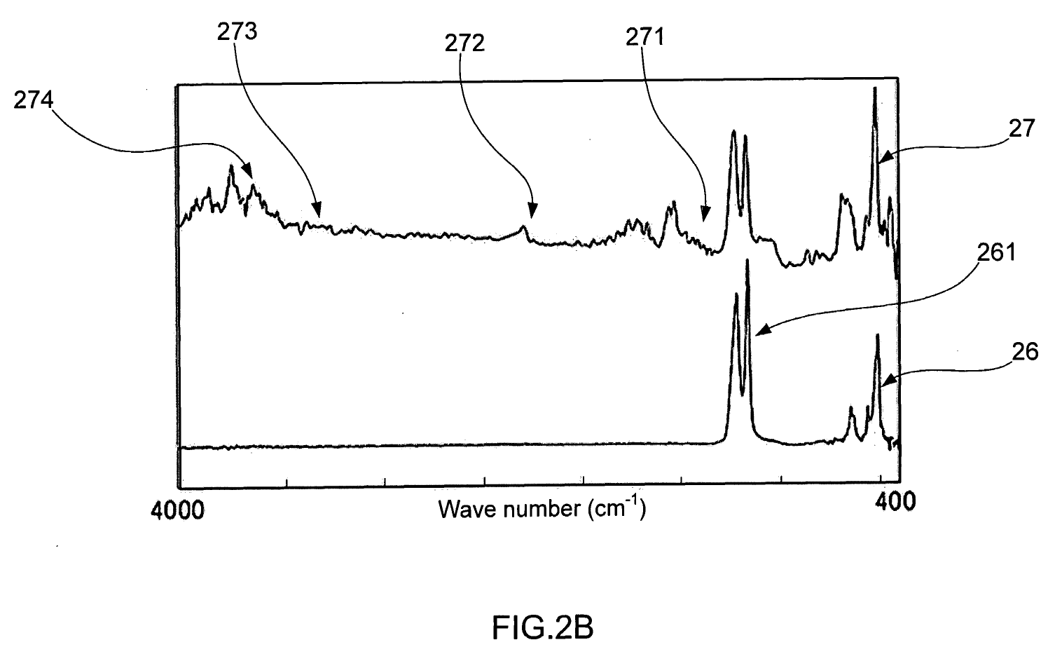

Please refer to FIG. 2, which is a view showing a flow chart of a first preferred embodiment. As shown in the figure, a first preferred embodiment uses a polymer film made of a stretchable Teflon to obtain a biomedical material of a hydrophilic polymer film according to the present invention, comprising the following steps:

(a1) Obtaining a stretchable Teflon to be cleaned with ultrasonic wave [21]: A stretchable Teflon is obtained to be cleaned with ultrasonic wave using an ethanol or a distilled water.

(b1) Processing a plasma deposited treatment to obtain a hydrophilic stretchable Teflon [22]: The cleaned stretchable Teflon is processed through a plasma deposited treatment under a vacuum pressure below 20 mtorr with 50 mtorr of HMDSZ to form a hydrophilic stretchable Teflon, where the working power is 10 W; and the plasma deposited treatment is processed for 10 min. Thus, a stretchable Teflon having hydrophilic HMDSZ is formed.

Please refer to FIG. 2A, which is a view showing changes in hydrophile of the first preferred embodiment. As shown in the figure, a polymer film of a stretchable Teflon is used; and, after a plasma deposited treatment, a stretchable Teflon having hydrophilic HMDSZ is formed. During the process, changes in hydrophile of the stretchable Teflon is shown in FIG. 2A. The plasma deposited treatment is processed with a working power of 10 W [23] for 10 min [24] to obtain a water contact angle [25] of 82 degrees (°). For a water contact angle for an unprocessed stretchable Teflon is 125°, a polymer film with a better hydrophile is obtained.

Please refer to FIG. 2B, which is a view showing a Fourier transform infrared spectrum of the first preferred embodiment. As shown in the figure, an unprocessed stretchable Teflon and a stretchable Teflon are obtained to processed through a Fourier transform infrared spectroscopy analysis to get a first spectrum curve [26] and a second spectrum curve [27], respectively. In the first spectrum curve [26], obtained from the unprocessed stretchable Teflon through the Fourier transform infrared spectroscopy analysis, obvious characteristic absorption peaks [261] of C—C and C—F are obtained between a wave number of 1160 cm⁻¹ (times per centimeter) and a wave number of 1210 cm⁻¹.

In the second spectrum curve [27], obtained through the Fourier transform infrared spectroscopy analysis from the stretchable Teflon after the plasma deposited treatment, a plurality of characteristic absorption peaks are obtained. The characteristic absorption peaks include a —CH₃ peak [271] at a wave number of 1410 cm⁻¹ owing to breaking the HMDSZ's link; a Si—H peak [272] between a wave number of 2100 cm⁻¹ and a wave number of 2160 cm⁻¹; a C—H peak [273] between a wave number of 2900 cm⁻¹ and a wave number of 2960 cm⁻¹; and an N—H peak [274] at a wave number of 3407 cm⁻¹.

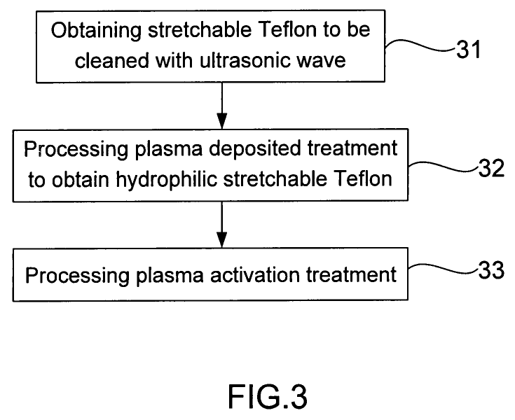

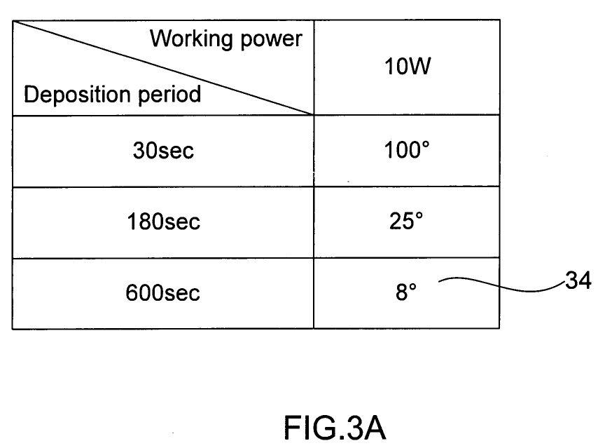

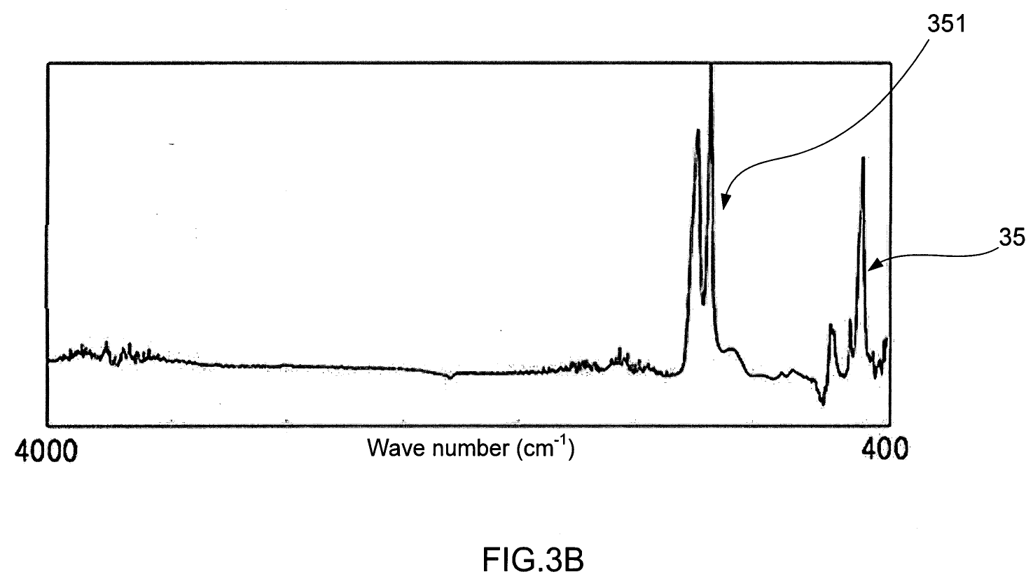

Please refer to FIG. 3, which is a view showing a flow chart of a second preferred embodiment. As shown in the figure, a second preferred embodiment uses a polymer film made of a stretchable Teflon to obtain a biomedical material of a hydrophilic polymer film according to the present invention, comprising the following steps:

(a2) Obtaining a stretchable Teflon to be cleaned with ultrasonic wave [31]: A polymer film made of a stretchable Teflon is obtained to be cleaned with ultrasonic wave using an ethanol or a distilled water.

(b2) Processing a plasma deposited treatment to obtain a hydrophilic stretchable Teflon [32]: The cleaned stretchable Teflon is processed through a plasma deposited treatment under a vacuum pressure below 20 mtorr with 50 mtorr of HMDSZ to form a hydrophilic stretchable Teflon, where the working power is 10 W; and the plasma deposited treatment is processed for 10 min. A stretchable Teflon having hydrophilic HMDSZ is formed.

(c2) Processing a plasma activation treatment [33]: The stretchable Teflon having hydrophilic HMDSZ is processed through a plasma activation treatment under a vacuum pressure below 20 mtorr with 200 mtorr of oxygen, where the working power is 50 W; and the plasma activation treatment is processed for 10 min.

Please refer to FIG. 3A, which is a view showing changes in hydrophile of the second preferred embodiment. As shown in the figure, a polymer film of a stretchable Teflon is used and is processed through a plasma deposited treatment and a plasma activation treatment. During the processes, changes in hydrophile of the stretchable Teflon are shown in FIG. 3A. The plasma activation treatment with a working power of 50 W for 10 min after the plasma deposited treatment with a working power of 10 W for 10 min is processed to obtain a water contact angle [34] of 8° for a stretchable Teflon having hydrophilic HMDSZ. For a water contact angle for an unprocessed stretchable Teflon is 125°, the water contact angle for the stretchable Teflon after the plasma deposited treatment and the plasma activation treatment is much smaller than the water contact angle for the stretchable Teflon after the plasma deposited treatment only. In the second embodiment, after the plasma deposited treatment, a layer of an organic silicon film is formed on the stretchable Teflon. During the plasma activation treatment, the organic silicon film on the stretchable Teflon is then reacted to obtain a better hydrophile than that of the original stretchable Teflon, a polymer film, after the plasma deposited treatment only.

Please refer to FIG. 3B, which is a view showing a Fourier transform infrared spectrum of the second preferred embodiment. As shown in the figure, a stretchable Teflon having hydrophilic HMDSZ is obtained to processed through a Fourier transform infrared spectroscopy analysis to obtain a third spectrum curve [35]. During the second preferred embodiment, a stretchable Teflon is processed through a plasma deposited treatment with an HMDSZ in step (b2) [32] to obtain a organic silicon film on the stretchable Teflon followed with a plasma activation treatment using oxygen in step (c2) [33]. It is found in the third spectrum curve [35] that, in the organic silicon film obtained from the polymer film after the plasma deposited treatment, a decomposition reaction and an oxidation reaction are happened to organic matter of the organic silicon film on the polymer film after the plasma activation treatment. Besides, C—O characteristic absorption peaks between a wave number of 900 cm⁻¹ and a wave number of 1100 cm⁻¹ are more obvious.

To sum up, the present invention is a plasma method for a biomedical material onto hydrophilic polymer sheet, where a biomedical material having a good hydrophile and a good bio-compatibility is obtained through simple processes.

The preferred embodiments herein disclosed are not intended to unnecessarily limit the scope of the invention. Therefore, simple modifications or variations belonging to the equivalent of the scope of the claims and the instructions disclosed herein for a patent are all within the scope of the present invention.

What is claimed is:

1. A plasma method for a biomedical material onto hydrophilic polymer sheet, comprising steps of:
(a) obtaining a polymer film to be cleaned with ultrasonic wave using a material selected from a group consisting of an ethanol and a distilled water;
(b) processing said cleaned polymer film through a plasma deposited treatment under a vacuum pressure with hexamethyldisilazane (HMDSZ) having a pressure to obtain a hydrophilic polymer film.

2. The method according to claim 1,
wherein said polymer film in step (a) is made of a material selected from a group consisting of a stretchable Teflon and a poly lactic-co-glycolic acid (PLGA).

3. The method according to claim 1,
wherein said vacuum pressure in step (b) is a pressure below 20 mtorr.

4. The method according to claim 1,
wherein said HMDSZ in step (b) has a pressure between 40 mtorr and 60 mtorr.

5. The method according to claim 1,
wherein said plasma deposited treatment in step (b) is processed for more than 5 minutes (min) under a working power between 5 watts (W) and 20 W.

6. A plasma method for a biomedical material onto hydrophilic polymer sheet, comprising steps of:
(a2) obtaining a polymer film to be cleaned with ultrasonic wave using a material selected from a group consisting of an ethanol and a distilled water;
(b2) processing said cleaned polymer film through a plasma deposited treatment under a vacuum pressure with HMDSZ having a pressure to obtain a hydrophilic polymer film; and
(c2) processing said hydrophilic polymer film through a plasma activation treatment under a vacuum pressure with oxygen having a pressure.

7. The method according to claim 6,
wherein said polymer film in step (a2) is made of a material selected from a group consisting of a stretchable Teflon and a PLGA.

8. The method according to claim 6, wherein said vacuum pressure in step (b2) is a pressure below 20 mtorr.

9. The method according to claim 6, wherein said HMDSZ in step (b2) has a pressure between 40 mtorr and 60 mtorr.

10. The method according to claim 6,
wherein said plasma deposited treatment in step (b2) is processed for more than 5 min under a working power between 5 W and 20 W.

11. The method according to claim 6,
wherein said vacuum pressure in step (c2) is a pressure below 20 mtorr.

12. The method according to claim 6,
wherein said oxygen in step (c2) has a pressure between 190 mtorr and 210 mtorr.

13. The method according to claim 6,
wherein said plasma activation treatment in step (c2) is processed for more than 5 min under a working power between 40 W and 60 W.
